(19) United States
(12) Patent Application Publication
(10) Pub. No.: US 2010/0224859 A1
(43) Pub. Date: Sep. 9, 2010

(54) Organic Light-Emitting Diodes with Electrophosphorescent-Coated Emissive Quantum Dots

(75) Inventors: Neil Gough, Manchester (GB); Christopher Williams, Morrisville, NC (US)

Correspondence Address: ARNOLD & KNOBLOCH, L.L.P., 4900 Woodway Dr., Suite 900, HOUSTON, TX, 77056, US

(73) Assignee: HCF Partners, LP, Houston, TX (US)

(21) Appl. No.: 12/738,404

(22) PCT Filed: Oct. 15, 2008
(86) PCT No.: PCT/US08/79898

§ 371 Date: Apr. 16, 2010

Related U.S. Application Data
(60) Provisional application No. 60/980,285, filed on Oct. 16, 2007.

(51) Int. Cl. H01L 33/04; H01L 21/20

(52) U.S. Cl. 257/13; 438/29; 257/E33.008; 257/E21.09

(57) ABSTRACT

The present invention provides a composition comprising quantum dots and a coating material that comprises an electro-phosphorescent moiety, and methods for producing and using the same. In particular, compositions of the invention are used in organic light emitting diodes (OLEDs), and electronic devices that utilize OLEDs.

### CROSS-REFERENCE TO RELATED APPLICATIONS

This application claims the priority benefit of U.S. Provisional Application No. 60/980,285, filed Oct. 16, 2007, which is incorporated herein by reference in its entirety.

### FIELD OF THE INVENTION

The present invention relates to a composition comprising quantum dots and a coating material that comprises an electro-phosphorescent moiety, and methods for producing and using the same.

### BACKGROUND OF THE INVENTION

Organic light-emitting diodes (OLEDs) are currently being widely investigated for applications in the flat-panel display industry, particularly for applications which require low power consumption, high color purity and long lifetimes. The basic structure of a multilayer OLED was introduced by Eastman-Kodak in 1987, and since then many developments have been made to improve the overall performance of these devices. One significant milestone was achieved with the development of an organic guest-host system, in which a small concentration of a fluorescent laser dye (guest) is co-evaporated with a host material. This advancement provided improved electroluminescence from the singlet state. It is believed that such a system relies on a Förster-type energy transfer process of the host singlet exciton to a guest singlet state. The internal quantum efficiency of such a system is generally believed to be limited to approximately 25% because about 75% of the excitons form in the triplet configuration, for which emission is forbidden by spin conservation.

More recently, some have reported increase in the internal quantum efficiency to nearly 100% through the use of electro-phosphorescent (EP) materials, which have the ability to emit from the triplet state. Without being bound by any theory, it is believed that this is accomplished by spin-orbit coupling, which mixes the singlet and triplet states and allows strong intersystem crossing (ISC) between the two. While the transfer of a singlet exciton to a fluorescent dopant occurs by the Förster mechanism, such a transition is not allowed by spin conservation for a triplet exciton, and therefore this transfer is believed to occur by the physical movement of charge, known as a Dexter transfer. It is also believed that excitons can form on electro-phosphorescent dopant molecules through direct charging for certain material configurations, giving rise to the high observed efficiencies for OLEDs based on these systems.

An alternative approach to improving OLEDs, particularly the color purity of emission, is by using inorganic semiconductor nanocrystals, known as quantum dots (QDs). Several groups have produced QD-OLEDs using either thin layers of quantum dots or quantum dot-polymer composites. Others have used quantum dots as one approach to achieving white emission for applications such as solid-state lighting.

In general, conventional methods are directed to achieving either the efficiency or the color purity of OLEDs. While a few methods may provide increase in both the efficiency and the color purity, there still remains a need for both increases in efficiency and color purity of OLEDs.

### SUMMARY OF THE INVENTION

Some aspects of the invention provide an organic light emitting diode (OLED) composition comprising a quantum dot, and a coating material in contact with the quantum dot. The coating material comprises an electro-phosphorescent moiety. In this manner, compositions of the invention comprise both quantum dots and electro-phosphorescence.

In some embodiments, electro-phosphorescent moiety is capable of Förster transfer of singlets, Dexter transfer of triplets, or a combination thereof.

Still in other embodiments, the quantum dot and the electro-phosphorescent moiety have similar emission spectra. While in other embodiments, the quantum dot and the electro-phosphorescent moiety have dissimilar emission spectra.

Yet in other embodiments, OLED compositions of the invention further comprise an emissive material. Exemplary emissive materials include, but are not limited to, BCP, TPBi, Alq3, or a combination thereof.

In other embodiments, the quantum dot is an inorganic semiconductor particle. In some instances, the quantum dot has a diameter of less than 25 nm. Yet in other instances, the quantum dot comprises a transition metal.

Still yet in other embodiments, the electro-phosphorescent moiety comprises an organometallic moiety. In some instances the organometallic moiety comprises a transition metal or a lanthanide metal.

While any of the known electro-phosphorescent moiety can be used in the invention, in some embodiments, the electro-phosphorescent moiety comprises FIr(pic), Ir(ppy)₃, Btp₂(acac), Bt₂(acac), or a combination thereof.

Yet in other embodiments, the coating material further comprises a linker. The linker can be non-covalently attached to the surface of the quantum dot, for example, by Van der Waal's force, an ionic interaction, hydrogen bonding, etc.

Other aspects of the invention provide methods for producing an organic light emitting diode (OLED) composition. The methods generally include coating a quantum dot with a coating material that comprises an electro-phosphorescent moiety.

Still other aspects of the invention provide organic light emitting diode (OLED) devices comprising:
a substrate;
an anode in physical contact with said substrate;
a hole injection/transport layer in electrical connection with said anode;
an electro-phosphorescent quantum dot layer in electrical connection with said hole injection/transport layer, wherein said electro-phosphorescent quantum dot layer comprises a quantum dot coated with a coating material comprising an electro-phosphorescent moiety; and
a cathode in electrical connection with said electro-phosphorescent quantum dot layer.

In some embodiments, the OLED devices further comprise one or more emission modification layers between the electro-phosphorescent quantum dot layer and the cathode. In some cases, the emission modification layers comprise:
a hole blocking layer in electrical connection with the electro-phosphorescent moiety;
an electron transport layer in electrical connection with the hole blocking layer;
an electron injection layer in electrical contact with the electron transport layer and the cathode.

Still in other embodiments, the electro-phosphorescent quantum dot layer further comprises one or more dopants.

Yet other aspects of the invention provide methods for producing an OLED device. The methods typically comprise:
producing a hole injection/transport layer on an anode;
producing a quantum dot layers on the hole injection/transport layer;
producing an electro-phosphorescent layer on the quantum dot layer;
optionally producing one or more emission modification layers on the electro-phosphorescent layer; and
producing a cathode on the emission modification layer or the optionally produced emission modification layer.

In some embodiments, the step of producing the emission modification layers comprises:
producing a hole blocking layer on the electro-phosphorescent layer;
producing an electron transport layer on the hole blocking layer;
producing an electron injection layer on the electron transport layer; and
producing a cathode on the electron injection layer.

### BRIEF DESCRIPTION OF THE DRAWINGS

FIG. 1 is a schematic representation of one particular embodiment of the present invention illustrating the structure of a quantum dot in close proximity to an electro-phosphorescent moiety;

FIG. 2 is a schematic representation of some of the various OLED device structures of the present invention comprising a layer of quantum dots coated with an electro-phosphorescent compound;

FIG. 3 is a graph of voltage versus luminance for an example device;

FIG. 4 is a graph of voltage versus current efficiency for an example device;

FIG. 5 is a graph of voltage versus current density for an example device; and

FIG. 6 is an electroluminescent spectra of an example device.

### DETAILED DESCRIPTION OF THE INVENTION

Both electro-phosphorescent (EP) dopants and quantum dots (QDs) offer many benefits to the emerging field of OLED displays and lighting. Conventional methods employ one or the other to achieve either efficiency or color purity, but not both. While there has been extensive research in achieving both efficiency and color purity of OLED displays, people have been seeking other methods besides a combination of EP and QDs. Surprisingly and unexpectedly, it has been discovered by the present inventors that a combination of EP and QDs provides increased color purity of OLED displays while also increasing efficiency. Accordingly, some aspects of the invention provide a composition comprising an EP moiety and a QD, methods for using and producing the same, and electronic devices comprising such a composition.

Some aspects of the invention combine both EP and QDs and their advantages into a single structure that can be easily incorporated into an OLED. There are at least two possibilities available in combining QDs and EP materials. The first method is to build an OLED structure comprising both a layer of QDs and EP materials. The second method is to use a QD in conjunction with a ligand or capping group possessing the desired electro-phosphorescent characteristics.

In one particular embodiment, an organic light emitting diode comprises: a substrate; an anode in physical contact with the substrate; a hole injection layer in electrical connection with the anode, a hole transport layer in electrical connection with the hole injection layer; a QD emission layer in electrical connection with the hole transport layer; an EP layer in electrical connection with the QD emission layer; a hole blocking layer in electrical connection with the EP layer; an electron transport layer in electrical connection with the hole blocking layer; an electron injection layer in electrical connection with the electron transport layer and a cathode in electrical connection with the electron injection layer.

Yet in another particular embodiment, an organic light emitting diode comprises: a substrate; an anode in physical contact with the substrate; a hole injection layer in electrical connection with the anode; a hole transport layer in electrical connection with the injection layer; an electro-phosphorescent quantum dot layer in electrical connection with the hole transport layer; a hole blocking layer in electrical connection with the electro-phosphorescent quantum dot layer; an electron transport layer in electrical connection with the hole blocking layer; a electron injection layer in electrical connection with the electron transport layer; and a cathode in electrical connection with the electron injection layer.

The composition of the one or more emission modification layers and other layers of the device are selected based on the desired function of the device. Several different options are described below.

As used herein, “layer” does not mean that a perfect layer of material is formed. Rather, as known in the art, certain defects such as pinholes or areas which do not have the material may be present, as long as the defects do not prevent the layer from having the desired characteristics. Also, “layer” may mean that in certain areas, there is more material thickness than in other areas. In specific embodiments, “layer” includes a partial layer up to multiple layers.

As used herein, when two materials are in “electrical connection” with each other, there is sufficient contact such that holes or electrons can pass from one material to another.

As used herein, when two moieties are “attached,” it is to be understood that there is not necessarily a covalent bond between the two moieties. The term “attach” and its grammatical variations refers to a coupling or joining of two or more chemical or physical elements. In some instances, attach can refer to a coupling of two or more atoms based on an attractive interaction, such that these atoms can form a stable structure. Examples of attachment include chemical bonds such as chemisorptive bonds, covalent bonds, ionic bonds, van der Waals force, and hydrogen bonds.

The electro-phosphorescent (EP) quantum dot (QD) layer can comprise one or more electro-phosphorescent quantum dots in a host material. As used herein the term “electro-phosphorescent quantum dots” refers to a composition comprising a material that comprises an EP moiety and a QD. The composition of the electro-phosphorescent quantum dots can be a mixture of different EP and/or QDs, or can comprise one type of EP material and one type of QD. The electro-phosphorescent quantum dot layer can also be one or more of the same or different electro-phosphorescent quantum dot compositions that are spin coated on the hole injection/transport layer or other layers in a semiconductor device.

In some embodiments, the electro-phosphorescent QD comprises a QD (which can be optionally passivated by an organic group such as a thiophene-containing group or other passivating group known in the art); and a layer of electro-phosphorescent group(s) attached to or coated onto the QD. In certain embodiments, the EP groups are spin coated or vapor deposited onto the QDs. These electro-phosphorescent quantum dots are useful in OLED devices as described herein. It should be appreciated that and it is well known in the art that OLEDs emit light when a voltage is applied to an OLED device.

The invention will be described with regard to the accompanying drawings which assist in illustrating various features of the invention. In this regard, the invention generally relates to a composition comprising a quantum dot and a material that comprises an electro-phosphorescence moiety, methods for using and producing the same, and devices that comprises the same. That is, the invention generally relates to OLED compositions, methods for producing and using the same, and devices that comprise such compositions. The description herein provides non-limiting illustrations of some embodiments and details of some embodiments of the invention.

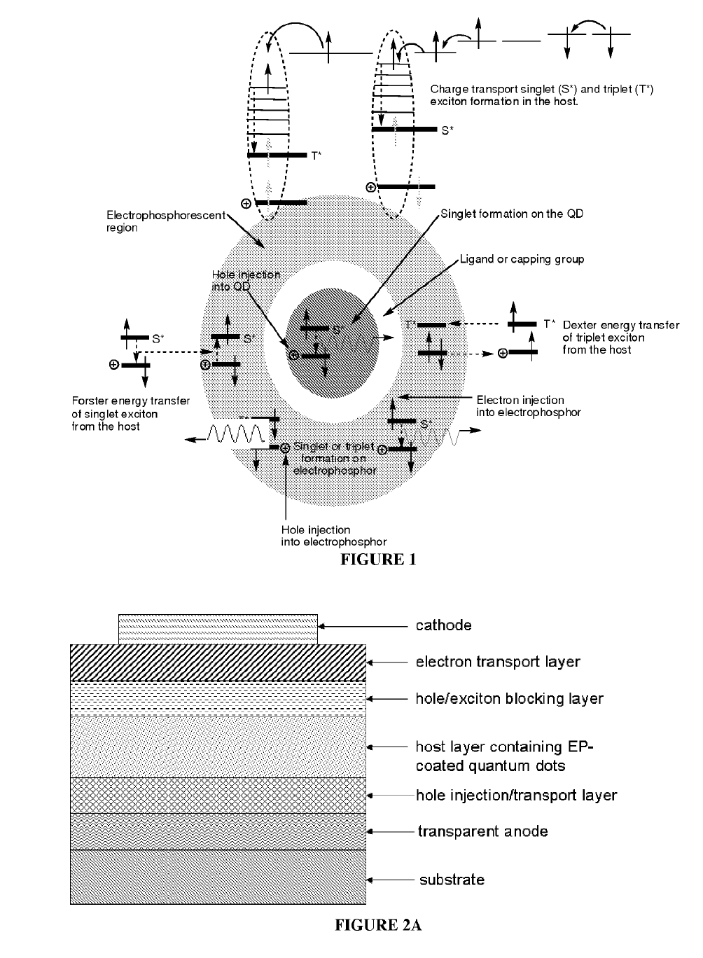

FIG. 1 is a schematic illustration of one embodiment of the composition comprising quantum dot and a material that comprises an electro-phosphorescent moiety. In this illustration, a coating material that comprises an electro-phosphorescent moiety is coated onto the quantum. The coating material also comprises a linker that is used to non-covalently attach the electro-phosphorescent moiety to the quantum dot. The linker is functionalized such that an electro-phosphorescent moiety can be attached to the linker.

In one aspect of the invention, the electro-phosphorescent moiety of the coating material is in close proximity to the host material such that efficient Förster transfer of singlets, Dexter transfer of triplets, or direct charging of either type of exciton, can be achieved. In some embodiments, the linker is short enough (e.g., less than 100 Angstroms) such that emissive singlet excitons can also be created on the QD by direct charging or possibly a Förster transfer from the host material or the EP moiety of the coating material. Both the EP moiety and the QD can contribute to emission. At least two configurations of the EP moiety and the QD are possible: (1) the EP moiety and the QD have similar emission spectra, which gives rise to enhanced color saturation and efficiency, and (2) the EP moiety and the QD have dissimilar or different emission spectra.

OLEDs comprising compositions of the invention can also have one or more additional emissive layers such as 2,9-Dimethyl-4,7-diphenyl-1,10-phenanhroline (BCP), 2,2′,2″-(1,3,5-Benzinetriyl)-tris(1-phenyl-1-H-benzimidazole) (TPBi) or other similar material, or a combination emissive/electron-transport layer, such as aluminum tris(8-hydroxyquinoline) (Alq3) or other known material, for a three- or more-component spectra. In some embodiments, compositions of the invention comprise a QD and a coating material that comprises a linker having one or more same or different EP moieties. When more than one coating materials are used, each coating material can be arranged in different layers or they can all be a mixture in one layer.

As used herein, “similar emission spectra” means the wavelength of maximum emission intensity in two different spectra are within 50 nm of each other. As used herein, emission spectra which are not similar means the wavelength of maximum emission intensity in two different spectra are more than 50 nm from each other.

The combined spectra of the multiple emitters can also be used as an approach to producing white light. In one aspect of the invention, a voltage-dependent spectrum is provided based on shifting the region of exciton formation and recombination. It is believed that at high current densities the device can be more susceptible to triplet-triplet annihilation effects, which has an effect on the dominant source or sources of emission within the device, as known in the art.

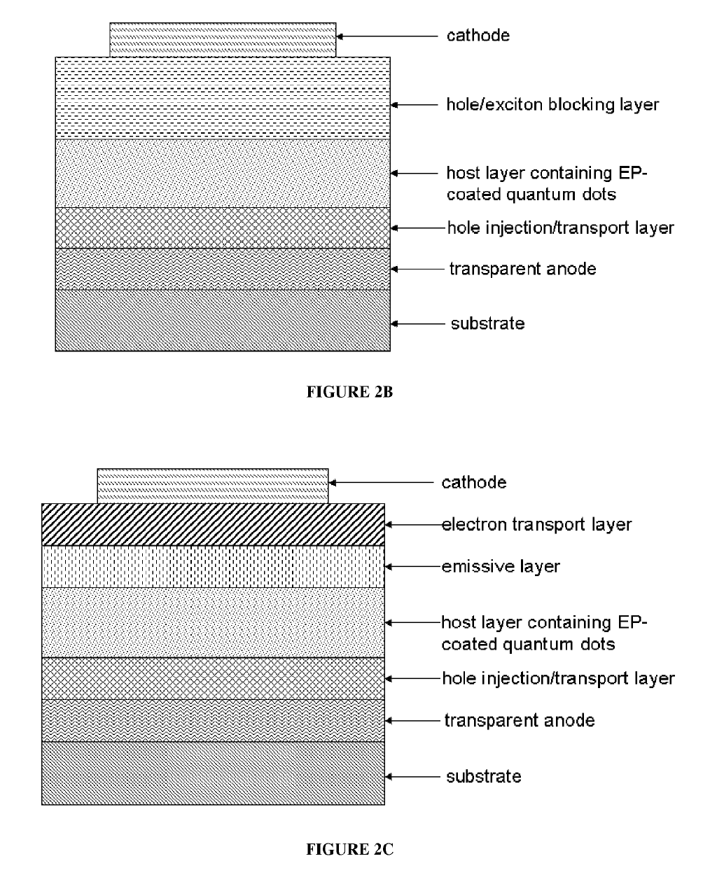

FIG. 2 is schematic illustrations of the some embodiments of the invention. In particular, FIG. 2 shows exemplary device structures comprising the quantum dots coated with a material comprising an electro-phosphorescent moiety. FIG. 2(a) shows a structure in which the source of emission is the EP-QD. In this configuration, the hole/exciton blocking layer serves to confine the emissive excitons to the region of the EP-QD emitter, and the electron transport layer facilitates efficient injection of electrons and the movement of these to the EP-QD emitters. In FIG. 2(b), a structure comprising a hole/exciton blocking layer without an electron transport layer is shown. For this device, the hole/exciton blocking layer is designed to confine excitons to the emissive region and transport electrons to the EP-QD emitters. FIG. 2(c) shows a structure that combines the EP-QD emitters with a second emissive layer and an electron transport layer. In this case, emission comes from the EP-QD and the emissive layer, which, in one embodiment, can combine to produce white light. The electron transport layer can facilitate injection of electrons from the cathode and movement of the electrons to the emissive region. In FIG. 2(d), a structure is shown that combines a second emissive layer with the EP-QDs, as well as a hole/exciton blocking layer. The emission from the emissive layer combines with that from the EP-QD, which in one embodiment, can produce a white light spectra. The hole/exciton blocking layer can confine the excitons to the region of the emissive layer and EP-QD emitters. In FIG. 2(e), an emissive layer is used to combine with the emission from the EP-QD emitters. The emissive layer can also act as a transport layer to carry the electrons to the emissive region. FIG. 2(f) shows a configuration that combines an emissive layer, a hole/exciton blocking layer and an electron transport layer. Light from the emissive layer combines with that from the EP-QDs layer to produce white light. The hole/exciton blocking layer is used to confine excitons to the region of the emissive layer and EP-QD emitters. The electron transport layer can facilitate injection of electrons into the device from the cathode and transport these electrons to the emissive layer and EP-QD emitters.

The overall fabrication and arrangement of an OLED is well known to one skilled in the art. Some examples are given here, however, all suitable known embodiments and components are intended to be included here. The substrate can be rigid or flexible. As is known in the art, a device can contain more than one layer that can be characterized as having the same technical function. For example, there can be more than one different layers in a device that function as an “emissive layer.” All such embodiments are intended to be included here. The substrate can be any suitable material including, but not limited to, plastic, metal, quartz and glass. The anode material can be any suitable material including, but not limited to, transparent indium tin oxide (ITO), gallium indium tin oxide, zinc indium tin oxide, titanium nitride, and polyaniline. The cathode can be any suitable material including, but not limited to, Al, Ba, Yb, Ca, a lithium-aluminum alloy, a magnesium-silver alloy, and any alloy thereof. The hole injection layer can be any suitable material including, but not limited to, copper phthalocyanine (CuPC), and a dispersion of poly(styrenesulfonate) in poly(3,4-ethylenedioxythiophene) (PEDOT:PSS). A suitable material for hole transport layer includes, but not limited to, N,N′-bis(naphthalen-1-yl)-N,N′-bis(phenyl)-benzidine (NPB) or poly(N,N′-bis(4-butylphenyl)-N,N′-bis(phenyl)benzidine (poly-TPD).

When used, the host material for the electro-phosphorescent quantum dot can be any suitable materials known to one skilled in the art. The material for emissive layer can be any suitable material known to one skilled in the art including, but not limited to, one or more of a small molecule electroluminescent material, a small molecule electro-phosphorescent material, a light emitting polymer, and a combination thereof. The material for hole-excitation blocking layer can be any suitable material known to one skilled in the art including, but not limited to, BCP, 3-(4-Biphenylyl)-4-phenyl-5-tert-butylphenyl-1,2,4-triazole (TAZ), and TPBi. The material for electron transport layer can be any suitable material known to one skilled in the art including, but not limited to, aluminum, gallium, indium, zinc and magnesium complexes, such as Alq3, and other suitable materials such as TPBi, TAZ, BCP, and any conjugated polymer. The structures corresponding to these abbreviations are known in the art.

In some embodiments, one or more materials comprising same or different EP moieties can be coated onto the same or different QDs and used in an OLED or other devices.

QDs are well known to one skilled in the art and are described in a variety of literatures. Various size QDs are useful in this invention. Without undue experimentation, one of ordinary skill in the art can select a QD that will be useful in the invention based on a variety of factors including, but not limited to, the desired optical characteristics of the OLED. In certain embodiments, the QD can be a core-shell structure, a QD-quantum well or a gradient QD, as known in the art.

All useful combinations of the various components and layers are intended to be included within the scope of the invention to the extent as if they were specifically listed.

Scheme 1 shows a synthesis of a linker that is capable of coordinating to both the QD surface and the transition metal ion of the EP moiety.

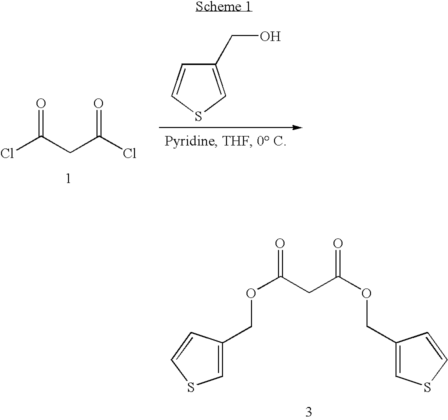

Although the linker in Scheme 1 comprises an α, β-dicarbonyl group, which coordinates with the EP moiety, and a thiophene group, which attaches to the QD, these are not the only useful functional groups. Other functional groups which are capable of performing the desired functions can be used. Suitable functional groups for such purposes are well known to one skilled in the art. For example, any functional group capable of attaching to the QD can be used in the linker. Thus, in cases where QD comprises a transition metal or a lanthanide, the linker can comprise a functional group that can attach to such a metal, e.g., sulfides, hydroxides, carboxylates, amines, etc. In certain embodiments, the linker can be attach to the QD through a thiophene, phosphine, carboxyl, amine group, alcohol, thiol, alkene, alkyne, ether, thioether, phosphine, amide, carboxylate, sulfonate, phosphate, quaternary ammonium, silane, sulfide, and other suitable groups as known in the art.

In certain embodiments, the linker of a coating material is attached to the QD through a carbon, nitrogen, sulfur, phosphorus or oxygen atom. Although the linker is shown as attaching to the QD and the EP group with “bi-dentate” ligands herein, the attachments can be mono-, bi-, tri-dentate, or other configurations known to one skilled in the art. The material comprising an EP moiety can be an oligomer or other suitable material known to one skilled in the art.

It should be noted that in one embodiment, the particular choice of the α, β-dicarbonyl ligand is influenced by its efficacy in SMP type compounds, such as the green dopant of the formula:

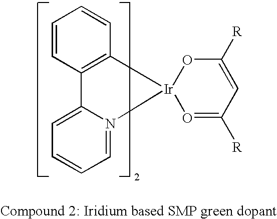

There are several methods available for incorporating an EP-moiety to the linker (e.g., compound 3 of Scheme 1) including: (1) attaching the linker to the surface of the QD followed by attaching an EP-moiety and (2) attaching an EP-moiety to the linker and then attaching the linker to the QD surface. Some of the methods for attaching an EP-moiety to the linker are illustrated in Schemes 2 and 3. It should be appreciated that the scope of the present invention for attaching an EP-moiety to the linker is not limited to such methods and includes other methods known to one skilled in the art, for example, using other suitable function groups.

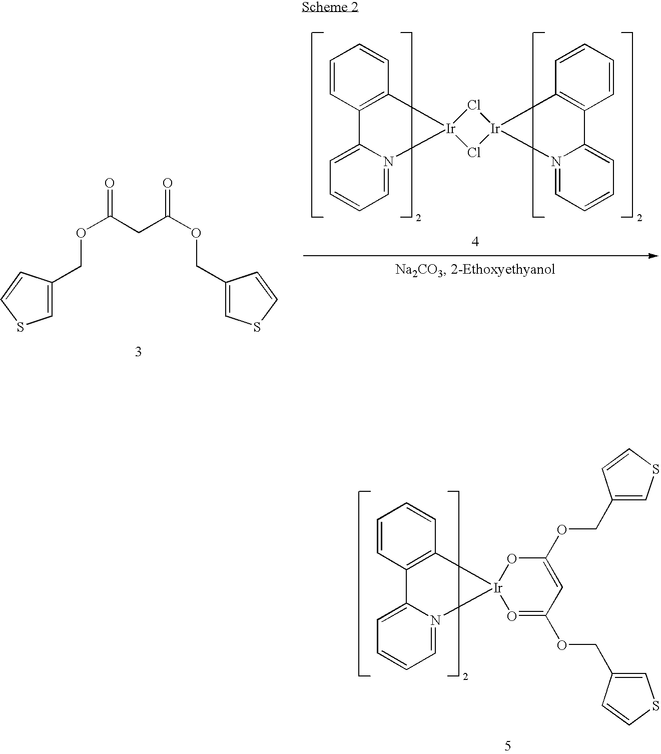

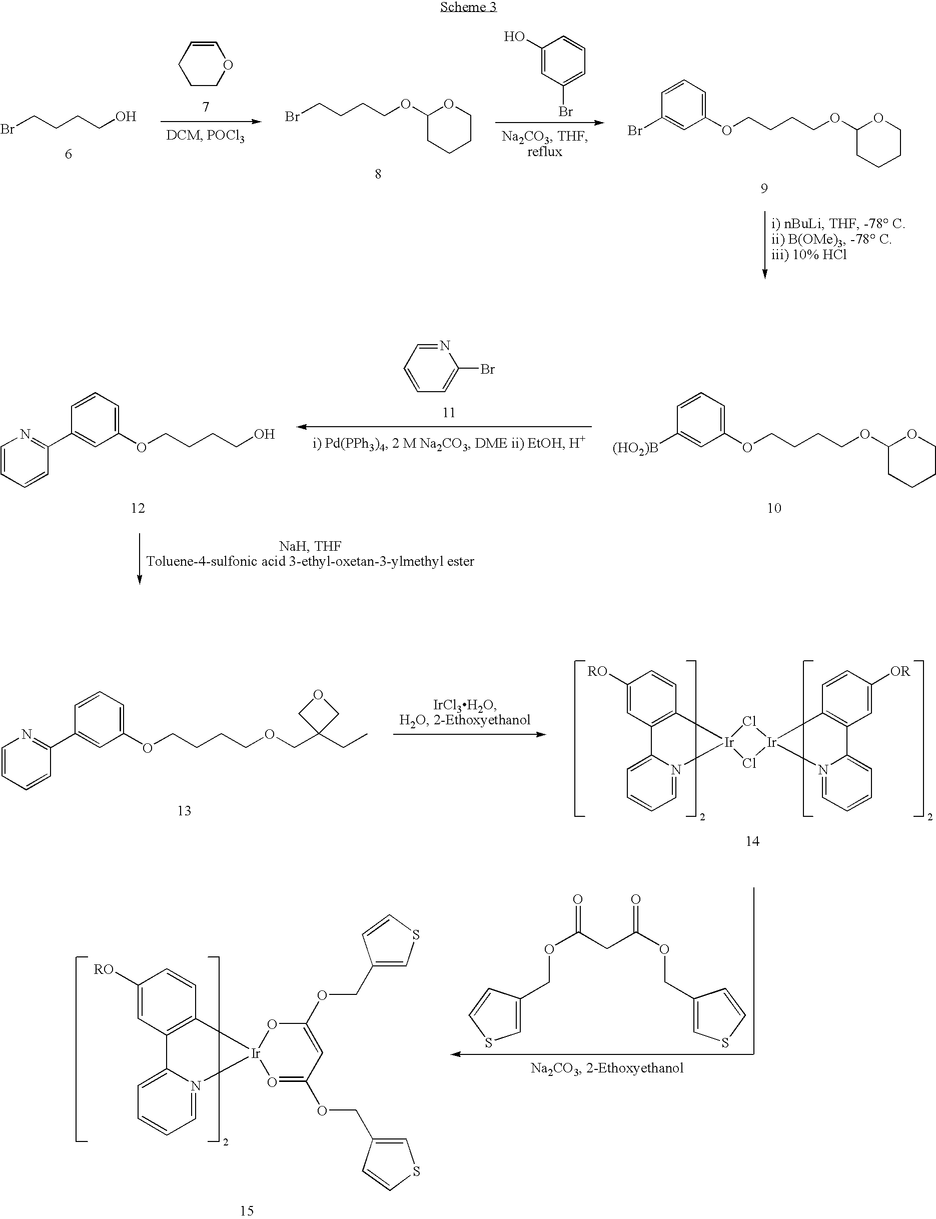

Schemes 4 and 5 are schematic representation of compounds 2 and 15, respectively, that are attached to quantum dots:

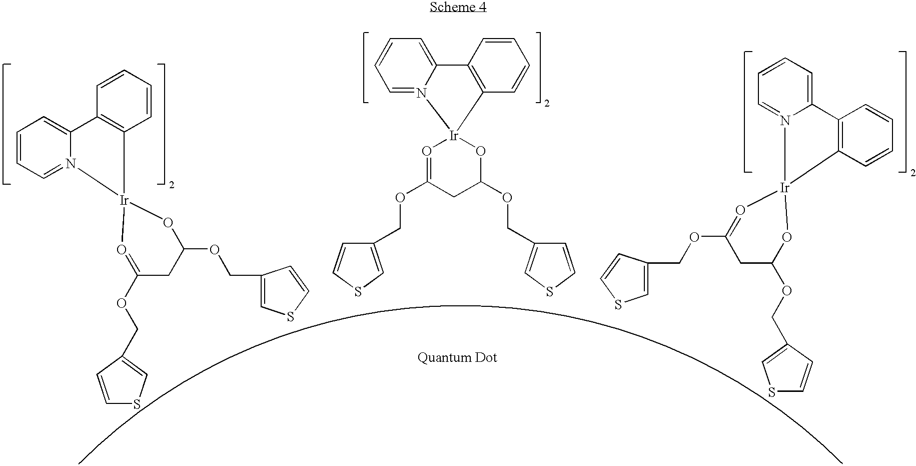

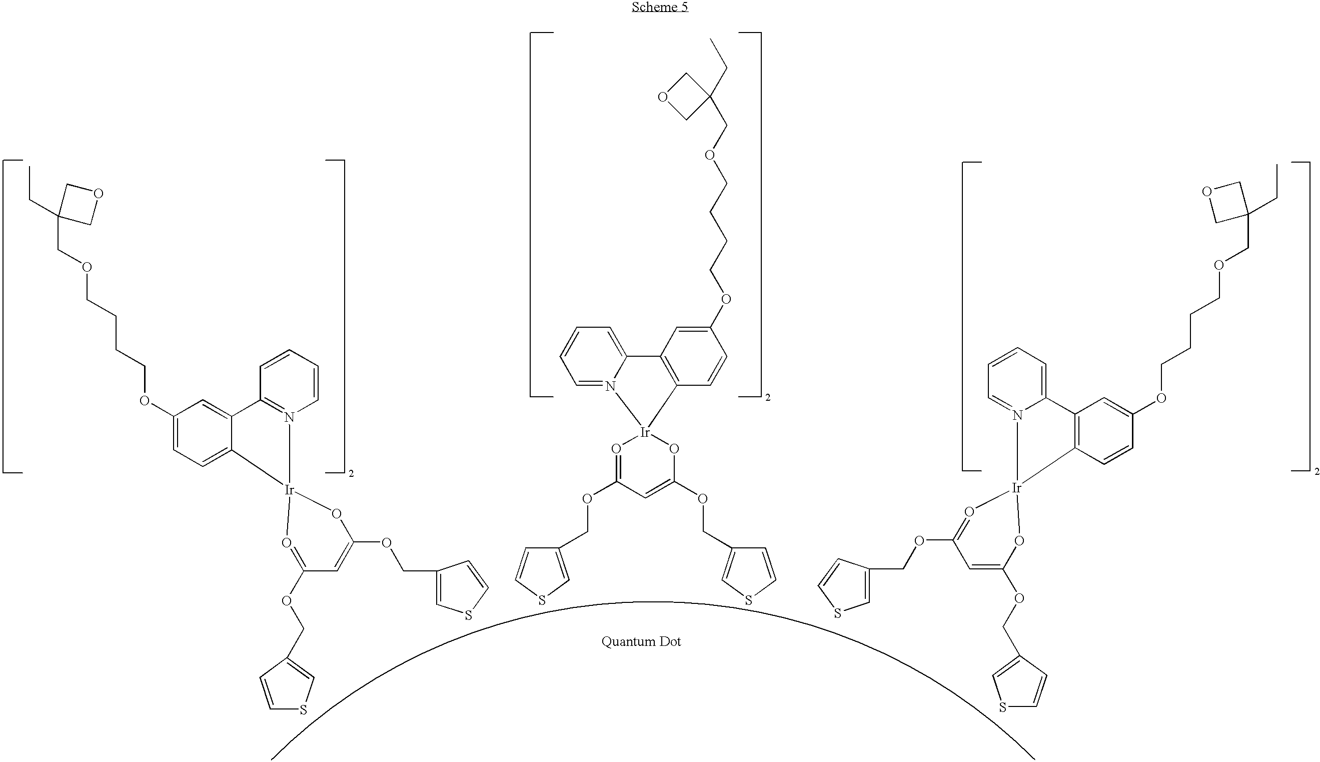

Schemes 6 and 7 below show alternative methods for producing the structures illustrated in Schemes 4 and 5, respectively. Briefly, in Schemes 6 and 7, the linker is bound to the quantum dot surface and then the electro-phosphorescence moiety is attached to the linker.

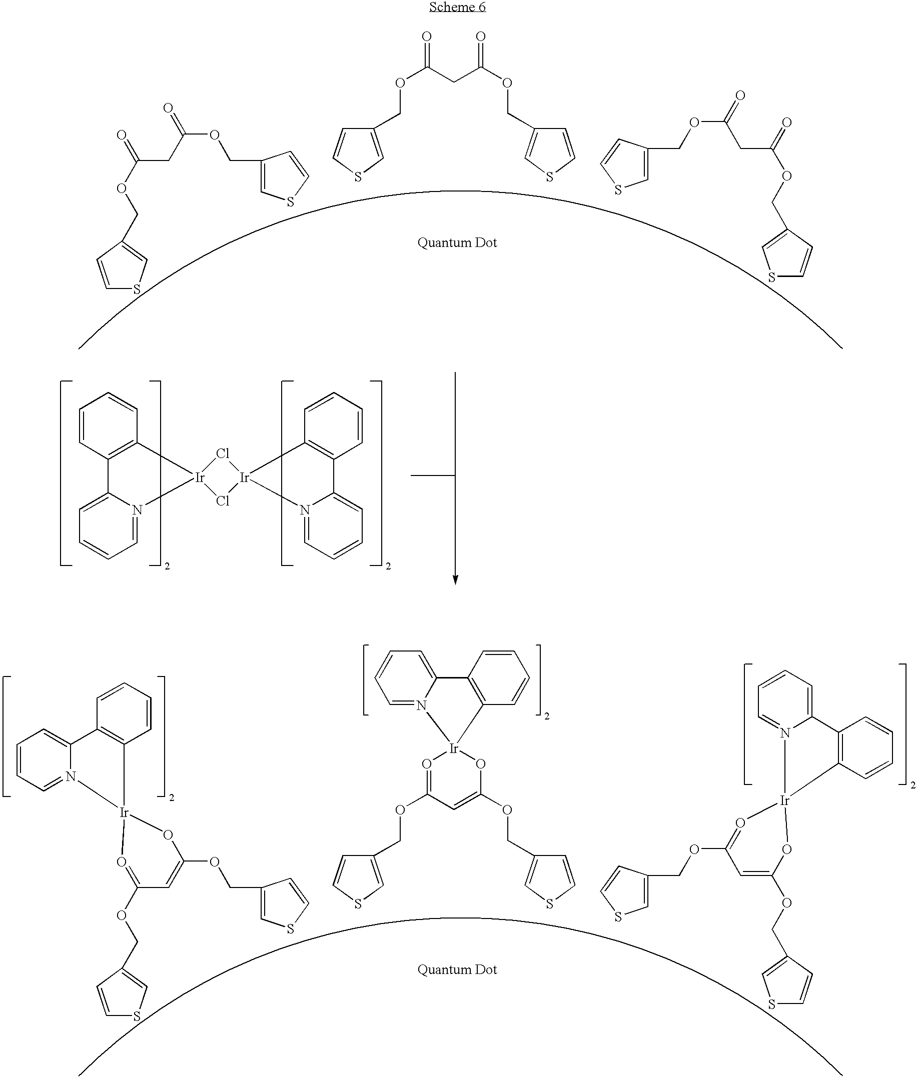

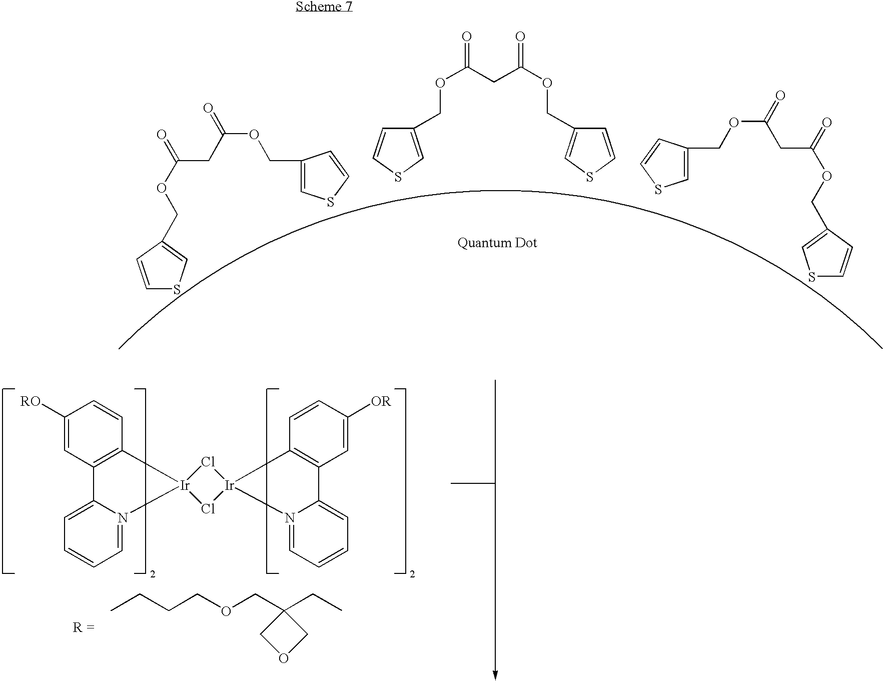

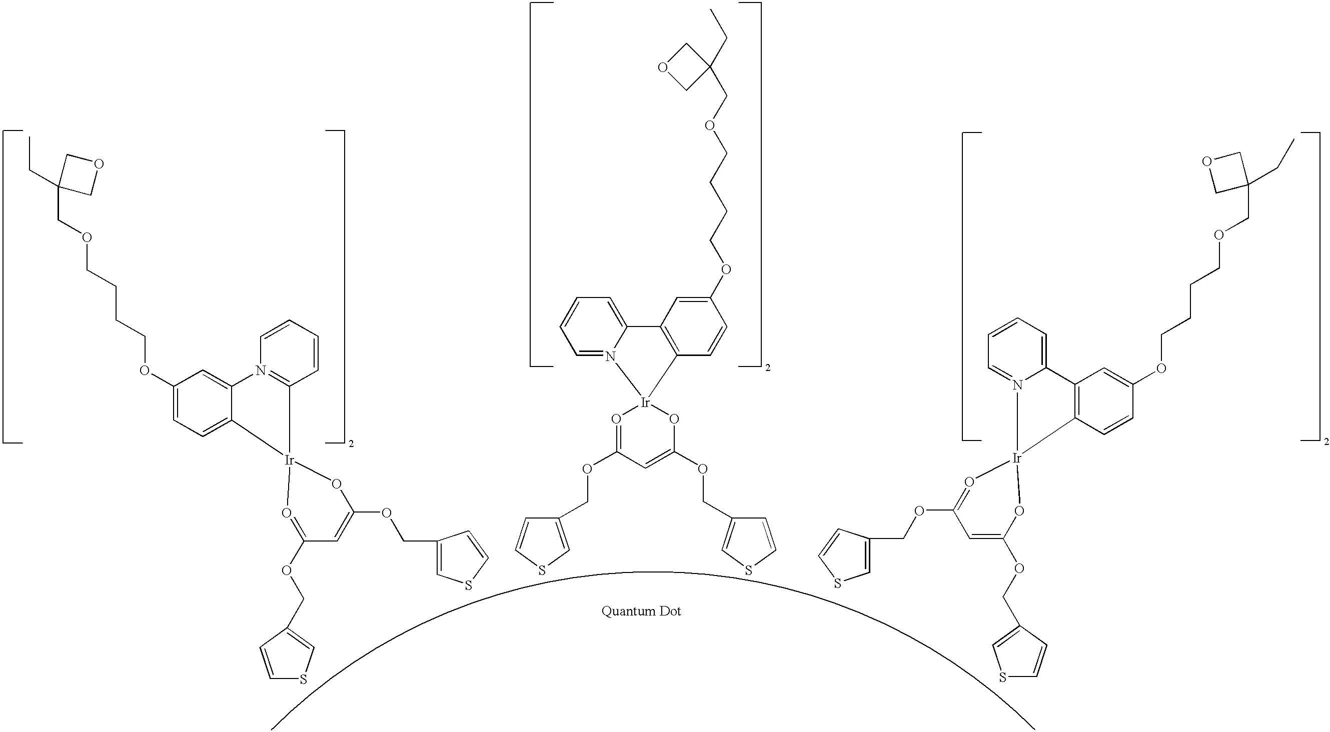

The EP moieties of Compounds 2 and 15, in combination with the selected QD provide green light. To obtain materials that emit red or blue light, linkers with the EP-moieties shown below can be used, respectively.

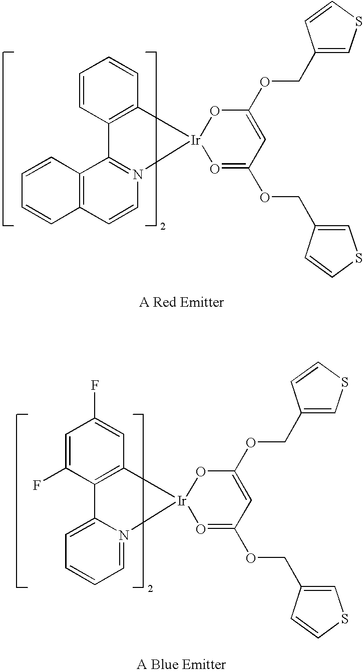

As known in the art, there are various emitters to choose from, depending on the desired emission spectrum. These emitters are well known to one skilled in the art and can be incorporated herein without undue experimentation. It is also well known to one skilled in the art that various mixtures of green, red, blue or other color emitters can be used in a device to provide the desired emission.

In order to encourage Förster transfer, the modified QDs can be spin coated on to the hole transport layer in the presence of a suitable host material, such as 4,4′-bis(cabazol-9-yl) biphenyl, which is typically with red and/or green emitters and 1,3-bis(carbozol-9-yl)benzene, which is typically used with blue emitters. The chemical structures of these exemplary host materials are shown below. Other suitable host materials are well known to one skilled in the art and can be incorporated in the methods and devices described herein by one of ordinary skill in the art without undue experimentation.

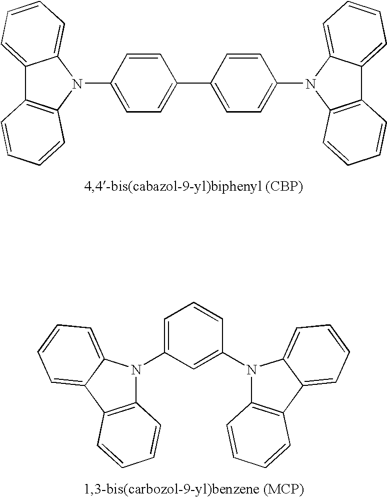

### Examples of Small Molecule Host Materials

As well as small molecule type host materials, polymeric materials such as, but not limited to, poly[(9,9-dioctylfluorenyl-2,7-diyl)-alt-co(9,9-(5′-pentenyl)-fluorenyl-2,7-diyl), which is abbreviated as PF28-pentenyl, can also be used as host materials.

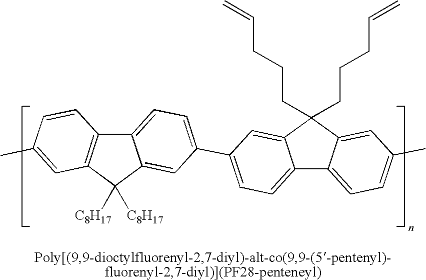

### Example of a Polymeric Host Material

QDs can be incorporated into OLEDs using a variety of techniques, including spin coating, screen printing and inkjet printing. One can achieve a desired optical property by the thickness of the QD layer.

Without being bound by any theory, it is believed that in order to achieve efficient charging and exciton formation within the modified QDs, each of the components need to have compatible band structures, i.e., close alignment of the respective highest occupied molecular orbital (HOMO) and lowest unoccupied molecular orbital (LUMO). It is believed that such a configuration serves several purposes. For example, as the hole-transport layer (HTL)/emissive layer (EML) and electron-transport layer (ETL)/EML interface, close alignment of the respective HOMO and LUMO allows hole and electrons to be injected into the emissive layer without needing to surpass a significant energy barrier, and confines the charges to the emissive region without allowing the charges to escape to the opposite contact. For the system of host:EP-QD described herein, a series of properly aligned energy levels of the host material, electro-phosphorescence moiety, and QD provide an efficient pathway for charge injection, exciton formation, exciton transfer and radiative emission.

The inorganic QDs, which in some embodiments form the basis of OLEDs, are believed to be predominately charged by direct injection. Therefore, a low barrier for hole and electron injection from the surrounding molecule, namely the host and EP, is desired. In one embodiment, this is achieved by using a host molecule having a large band-gap that provides low injection barriers.

In some embodiments, a pathway for charge transfer from the QD to the triplet emitter is useful. This is typically achieved by using an EP moiety having an equal or slightly smaller gap relative to the QD. Even if the gap of the EP moiety is equal or larger than that of the QD, transfer of one type of carrier can still occur by way of a resonant transfer between aligned HOMO or LUMO. Significant transfer of both charges and excitons is believed to occur from the host to the EP moiety, which requires the guest EP moiety to have a smaller gap than the EP moiety for Förster transfer of singlet excitons and Dexter transfer of triplet excitons. For direct charging of the EP moiety, a proper alignment of levels allows one type of carrier to be injected from the QD (as discussed above), and the second type of carrier from the host. These factors are useful in tailoring the OLED to the desired outcome. Incorporation of these factors in a device and components thereof can be carried out by one of ordinary skill in the art without undue experimentation using the description provided herein.

Additional objects, advantages, and novel features of this invention will become apparent to those skilled in the art upon examination of the following examples thereof, which are not intended to be limiting. In the Examples, procedures that are constructively reduced to practice are described in the present tense, and procedures that have been carried out in the laboratory are set forth in the past tense.

### Examples

When a compound is described herein such that a particular isomer or enantiomer of the compound is not specified, for example, in a formula or in a chemical name, that description is intended to include each isomers and enantiomer of the compound described individual or in any combination. One of ordinary skill in the art will appreciate that methods, device elements, starting materials, dopants, and synthetic methods other than those specifically exemplified can be employed in the practice of the invention. All art-known functional equivalents, of any such methods, device elements, starting materials, dopants, and synthetic methods are intended to be included within the scope of this invention. Whenever a range is given, for example, a wavelength range, a time range, or a composition range, all intermediate ranges and subranges, as well as all individual values included in the ranges given are intended to be included within the scope of the invention.

In order to study the respective HOMO and LUMO levels of the new materials provided, and predict and model their interactions and to achieve this type of device engineering, measurement systems known in the art such as cyclic voltametry (CV), ultraviolet photoemission spectroscopy (UPS), and inverse photoemission spectroscopy (IPES) are typically used.

The following procedure describes one example of an OLED device prepared and tested using one embodiment of the invention.

A multilayer OLED was fabricated using a combination of solution processing and chemical vapor deposition (CVD). The structure of this stack was indium tin oxide (ITO), PEDOT:PSS (25.00 nm), poly-TPD (35.00 nm), QD (7.00 nm diameter, nominally three layers), IrPPy₃ (2.80 nm), TPBi (40.70 nm) Alq₃ (15.00 nm), LiF (1.50 nm) and a cathode comprising Al.

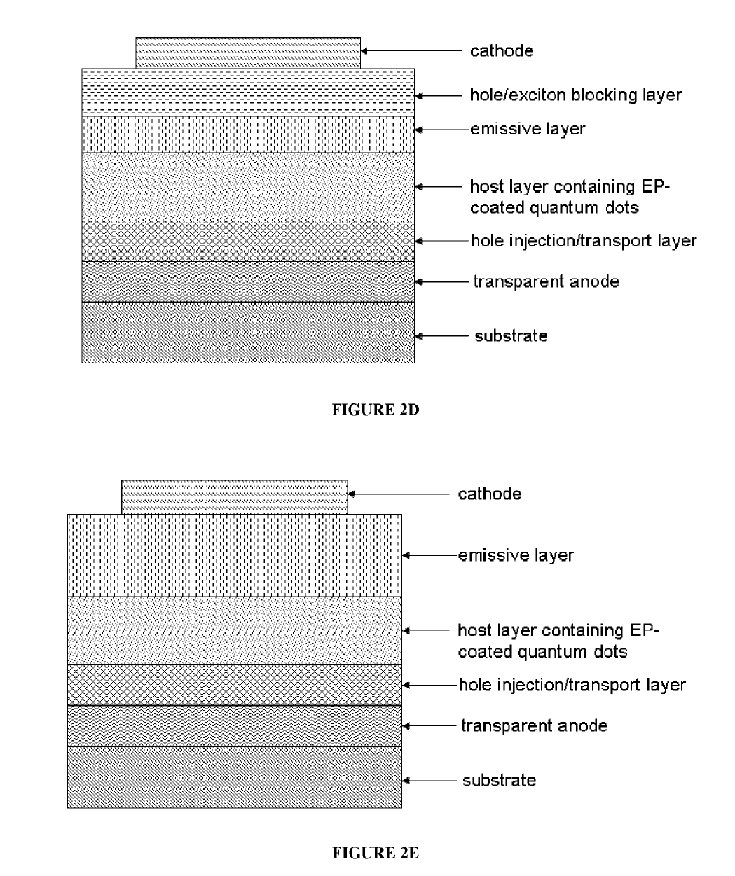

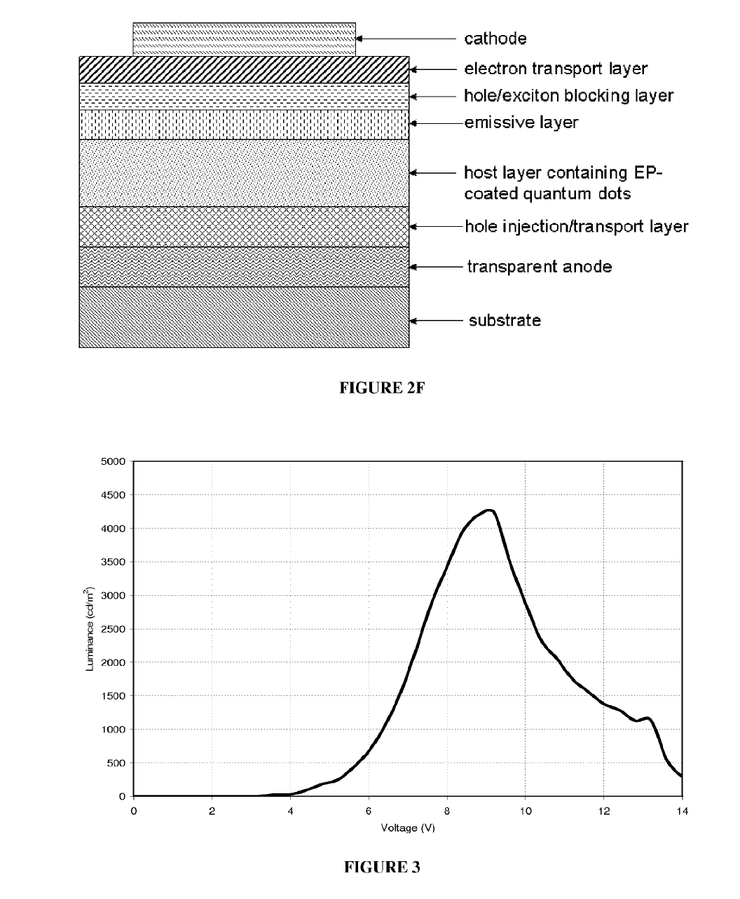

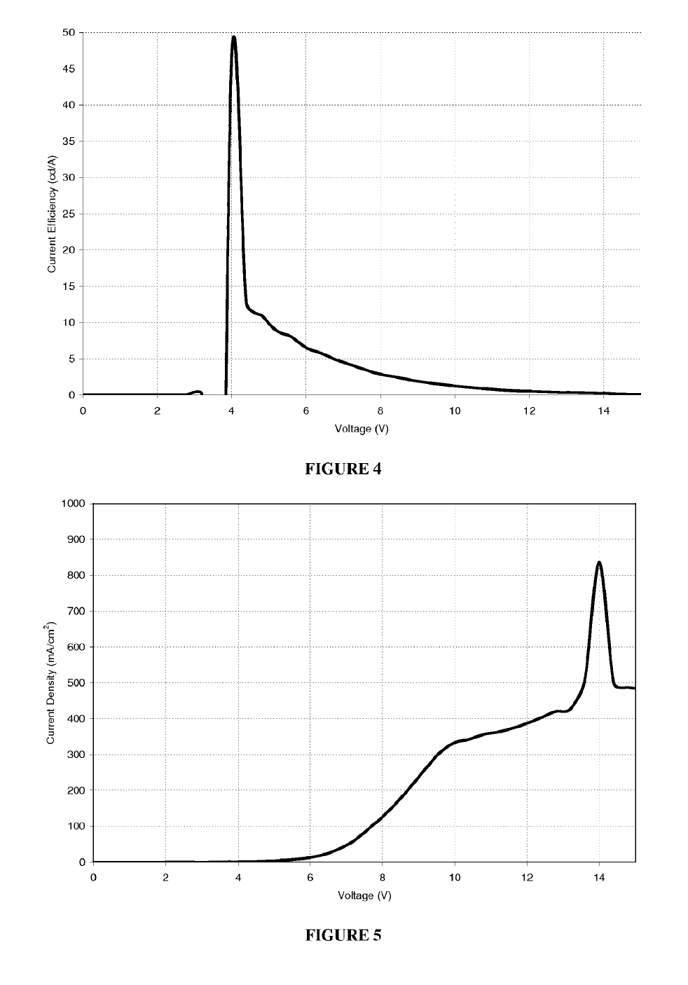

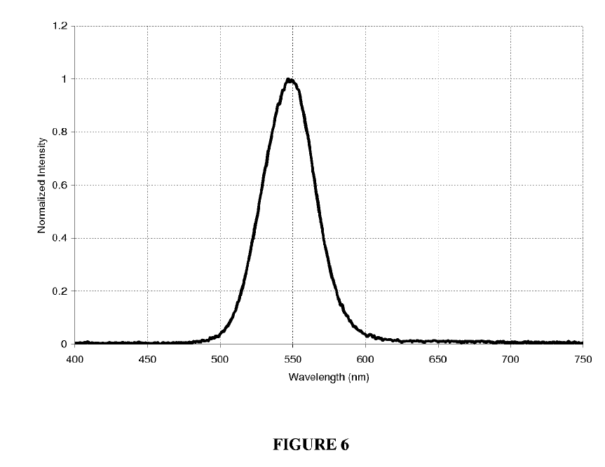

ITO-coated glass was cleaned thoroughly by sonication in a 2% Tergitol solution, followed by a rinsing in de-ionized water and immersion for 10 minutes in a 5:1:1 solution of DI water:ammonium hydroxide:hydrogen peroxide heated to 70° C. Substrates were then rinsed with deionized (DI) water and sonicated in acetone and methanol for 15 minutes each. After drying with nitrogen, they were cleaned with UV/ozone. Spin-coating of PEDOT:PSS, the poly-TPD and QD layers was performed in a nitrogen-filled glove box. A 3:5 solution (0.3 mL) of Baytron P in methanol was cast onto the ITO substrate. After the solution had completely wet the surface, the substrate was accelerated to 3000 rpm for 1 second, then to 6000 rpm and held at that rate for 30 seconds. The film was annealed on a hotplate inside the glove box at 125° C. for 10 minutes. After annealing, the substrate was placed on the spin-coater, and a 10 mg/mL solution (0.1 mL) of poly-TPD in toluene was dropped onto the substrate surface. The substrate was accelerated to 3000 rpm and held at this rate for 60 seconds. The resultant film was annealed at 60° C. for 30 minutes. A solution of 3 mg/mL of QDs in octane was cast onto the surface of the substrate. The substrate was spun at 4000 rpm for one minute. Any suitable QD including, but not limited to, those described in US Patent Publication Number 2007/0111324, which is incorporated herein by reference in its entirety, can be used. The substrate with the PEDOT:PSS/poly-TPD/QD tri-layer was moved in an inert atmosphere to a vacuum chamber. A 2.8 nm film of Ir(ppy)₃ was deposited onto the substrate by thermal evaporation at a rate of about 0.1 Å s⁻¹, followed by a 40.70 nm thick layer of TPBi and a 15 nm thick layer of Alq₃, deposited at a rate of about 5.0 Å s⁻¹. Film deposition was carried out at a base pressure of 2×10⁻⁶ mbar. The chamber was vented and a shadow masked for depositing patterned cathodes was placed over the device. The device was placed back into the chamber and pumped to a base pressure of 2×10⁻⁶ mbar. A bi-layer of lithium fluoride and aluminum was deposited using thermal evaporation at a rate of about 0.1 Å s⁻¹ for LiF and about 5-25 Å s⁻¹ for Al. Finished devices were removed from the chamber and characterized under an inert atmosphere. See FIGS. 3-6 for various characteristics of the device.

The foregoing discussion of the invention has been presented for purposes of illustration and description. The foregoing is not intended to limit the invention to the form or forms disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed:

1. An organic light emitting diode (OLED) composition comprising a quantum dot, and a coating material in contact with said quantum dot, wherein said coating material comprises an electro-phosphorescent moiety.

2. The OLED composition of claim 1, wherein said electro-phosphorescent moiety is capable of Förster transfer of singlets, Dexter transfer of triplets, or a combination thereof.

3. The OLED composition of claim 1, wherein said quantum dot and said electro-phosphorescent moiety have similar emission spectra.

4. The OLED composition of claim 1, wherein said quantum dot and said electro-phosphorescent moiety have dissimilar emission spectra.

5. The OLED composition of claim 1 further comprising an emissive material.

6. The OLED composition of claim 5, wherein said emissive material comprises BCP, TPBi, Alq₃, or a combination thereof.

7. The OLED composition of claim 1, wherein said quantum dot is an inorganic semiconductor particle.

8. The OLED composition of claim 7, wherein said quantum dot has a diameter of less than 25 nm.

9. The OLED composition of claim 7, wherein said quantum dot comprises a transition metal.

10. The OLED composition of claim 1, wherein said electro-phosphorescent moiety comprises an organometallic moiety.

11. The OLED composition of claim 10, wherein said organometallic moiety comprises a transition metal or a lanthanide metal.

12. The OLED composition of claim 1, wherein said electro-phosphorescent moiety comprises FIr(pic), Ir(ppy)₃, Btp₂(acac), Bt₂(acac), or a combination thereof.

13. The OLED composition of claim 1, wherein said coating material further comprises a linker that is non-covalently attached to the surface of said quantum dot.

14. A method for producing an organic light emitting diode (OLED) composition comprising coating a quantum dot with a coating material comprising an electro-phosphorescent moiety.

15. An organic light emitting diode (OLED) device comprising:
a substrate;
an anode in physical contact with said substrate;
a hole injection/transport layer in electrical connection with said anode;
an electro-phosphorescent quantum dot layer in electrical connection with said hole injection/transport layer, wherein said electro-phosphorescent quantum dot layer comprises a quantum dot coated with a coating material comprising an electro-phosphorescent moiety; and
a cathode in electrical connection with said electro-phosphorescent quantum dot layer.

16. The OLED device of claim 15 further comprising one or more emission modification layers in between said electro-phosphorescent quantum dot layer and said cathode.

17. The OLED device of claim 16, wherein said emission modification layers comprise:
a hole blocking layer in electrical connection with said electro-phosphorescent moiety;
an electron transport layer in electrical connection with said hole blocking layer;
an electron injection layer in electrical contact with said electron transport layer and said cathode.

18. The OLED device of claim 15, wherein said electro-phosphorescent quantum dot layer further comprises one or more dopants.

19. A method for producing an OLED device comprising:
producing a hole injection/transport layer on an anode;
producing a quantum dot layers on the hole injection/transport layer;
producing an electro-phosphorescent layer on the quantum dot layer;
optionally producing one or more emission modification layers on the electro-phosphorescent layer; and
producing a cathode on the emission modification layer or the optionally produced emission modification layer.

20. The method of claim 19, wherein said step of producing the emission modification layers comprises:
producing a hole blocking layer on the electro-phosphorescent layer;
producing an electron transport layer on the hole blocking layer;
producing an electron injection layer on the electron transport layer; and
producing a cathode on the electron injection layer.
